(19) United States
(12) Patent Application Publication
(10) Pub. No.: US 2010/0133534 A1
(43) Pub. Date: Jun. 3, 2010

(54) INTEGRATED CIRCUIT PACKAGING SYSTEM WITH INTERPOSER AND FLIP CHIP AND METHOD OF MANUFACTURE THEREOF

(76) Inventors: Byung Tai Do, Singapore (SG); Reza Argenty Pagaila, Singapore (SG); Linda Pei Ee Chua, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/327,811

(22) Filed: Dec. 3, 2008

(51) Int. Cl. H01L 21/56; H01L 23/00

(52) U.S. Cl. 257/48; 438/124; 257/E21.502; 257/E23.001

(57) ABSTRACT

A method of manufacture of an integrated circuit packaging system includes: providing an interposer having a first side and a second side with the first side having a device contact and an interconnect contact and with the second side having a test pad; mounting an integrated circuit over the device contact; and applying an underfill between the integrated circuit and the interposer.

### TECHNICAL FIELD

The present invention relates generally to an integrated circuit packaging system and more particularly to a system for an integrated circuit packaging system with an interposer.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made therefrom. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Different challenges arise from increased functionality integration and miniaturization. For example, a semiconductor product having increased functionality may be made smaller but may still be required to provide a large number of inputs/outputs (I/O). The semiconductor product also needs to be readily testable while still providing smaller size. Further, increased performance of semiconductor product put additional challenges on the semiconductor product during test and in the field.

Thus, a need still remains for an integrated circuit packaging system providing low cost manufacturing, improved yield, improved reliability, and improved testability. In view of the ever-increasing need to save costs and improve efficiencies, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing an interposer having a first side and a second side with the first side having a device contact and an interconnect contact and with the second side having a test pad; mounting an integrated circuit over the device contact; and applying an underfill between the integrated circuit and the interposer.

The present invention provides an integrated circuit packaging system including: an interposer having a first side and a second side with the first side having a device contact and an interconnect contact and with the second side having a test pad; an integrated circuit over the device contact; and an underfill between the integrated circuit and the interposer.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in a first embodiment of the present invention.

FIG. 2 is a cross-sectional view of the integrated circuit packaging system along line 2-2 of FIG. 1.

FIG. 3 is a top view of an integrated circuit package-in-package system in a first application example of the integrated circuit packaging system of FIG. 1 in a second embodiment of the present invention.

FIG. 4 is a cross-sectional view of the integrated circuit package-in-package system along line 4-4 of FIG. 3.

FIG. 5 is a cross-sectional view of an integrated circuit package-in-package system in a second application example of the integrated circuit packaging system of FIG. 1 as exemplified by the top view of FIG. 3 in a third embodiment of the present invention.

FIG. 6 is a cross-sectional view of an integrated circuit package-in-package system in a third application example of the integrated circuit packaging system of FIG. 1 as exemplified by the top view of FIG. 3 in a fourth embodiment of the present invention.

FIG. 7 is a cross-sectional view of an integrated circuit package-in-package system in a fourth application example of the integrated circuit packaging system of FIG. 1 as exemplified by the top view of FIG. 3 in a fifth embodiment of the present invention.

FIG. 8 is a top view of an integrated circuit package-in-package system in a fifth application example of the integrated circuit packaging system of FIG. 1 in a sixth embodiment of the present invention.

FIG. 9 is a cross-sectional view of the integrated circuit package-in-package system along line 9-9 of FIG. 8.

FIG. 10 is a top view of an integrated circuit package-in-package system in a sixth application example of the integrated circuit packaging system of FIG. 1 in a seventh embodiment of the present invention.

FIG. 11 is a cross-sectional view of the integrated circuit package-in-package system along line 11-11 of FIG. 10.

FIG. 12 is a cross-sectional view of an integrated circuit package-in-package system in a seventh application example of the integrated circuit packaging system of FIG. 1 as exemplified by the top view of FIG. 10 in an eighth embodiment of the present invention.

FIG. 13 is a top view of an integrated circuit package-in-package system in an eighth application example of the integrated circuit packaging system of FIG. 1 in a ninth embodiment of the present invention.

FIG. 14 is a cross-sectional view of the integrated circuit package-in-package system along line 14-14 of FIG. 13.

FIG. 15 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation.

In addition, where multiple embodiments are disclosed and described having some features in common, for clarity and ease of illustration, description, and comprehension thereof, similar and like features one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the invention, regardless of its orientation. The term “vertical” refers to a direction perpendicular to the horizontal as just defined. Terms, such as “above”, “below”, “bottom”, “top”, “side”(as in “sidewall”), “higher”, “lower”, “upper”, “over”, and “under”, are defined with respect to the horizontal plane, as shown in the figures. The term “on” means that there is direct contact among elements.

The term “processing” as used herein includes deposition of material or photoresist, patterning, exposure, development, etching, cleaning, and/or removal of the material or photoresist as required in forming a described structure.

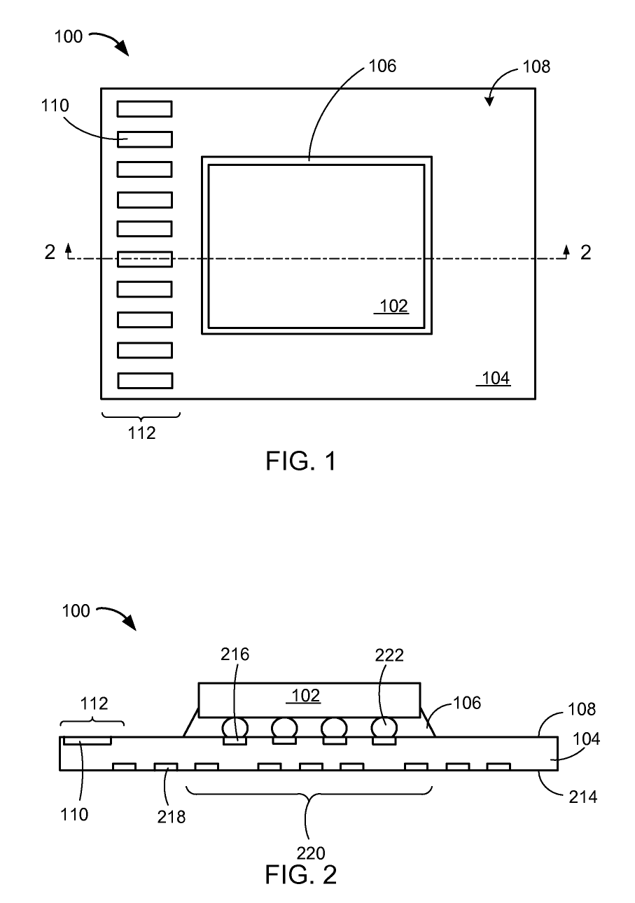

Referring now to FIG. 1, therein is shown a top view of an integrated circuit packaging system 100 in a first embodiment of the present invention. The top view depicts an integrated circuit 102, such as a flip chip, mounted over an interposer 104, such as a laminated substrate, with an underfill 106 in between. The interposer 104 includes a first side 108 having a row of interconnect contacts 110 at a peripheral portion 112 of the interposer 104.

The interconnect contacts 110 are sized to provide surface areas for reliable connection. For example, the surface area of each of the interconnect contacts 110 are sufficient large for robust and reliable wire bonding onto the interconnect contacts 110.

For illustrative purposes, the integrated circuit packaging system 100 is shown with one row of the interconnect contacts 110, although it is understood that the integrated circuit packaging system 100 can have a different configuration with the interconnect contacts 110. For example, the integrated circuit packaging system 100 can have multiple rows of the interconnect contacts 110. The rows can be staggered or in-line, as examples.

Referring now to FIG. 2, therein is shown a cross-sectional view of the integrated circuit packaging system 100 along line 2-2 of FIG. 1. The integrated circuit packaging system 100 includes the interposer 104 having the first side 108 and a second side 214. The first side 108 can include device contacts 216 and the interconnect contacts 110. The second side 214 can include test pads 218.

The device contacts 216 can be at an interior portion 220 of the interposer 104. The device contacts 216 and the interconnect contacts 110 are exposed at the first side 108 of the interposer 104. The test pads 218 can be exposed at the second side 214 of the interposer 104.

The integrated circuit 102 can be mounted over the interposer 104 with electrical connectors 222, such as solder bumps or conductive bumps. The electrical connectors 222 can connect to the device contacts 216. The underfill 106 can be between the integrated circuit 102 and the interposer 104. The underfill 106 can surround the electrical connectors 222.

The device contacts 216 are sized to provide sufficient large surface areas for the electrical connectors 222 to attach to the device contacts 216 while small enough to provide the density of interconnects or input/outputs (I/O) of the integrated circuit 102. The device contacts 216 are preferably smaller than the interconnect contacts 110.

The test pads 218 can be formed to withstand repeated test connection impact forces. For example, the test pads 218 can be formed with multiple layers of conductive layers of similar or different materials. The test pads 218 can also be formed with lower resistive material than the device contacts 216 and the interconnect contacts 110. For example, the test pads 218 can be formed with gold (Au) while the device contacts 216 and the interconnect contacts 110 can be formed with copper (Cu).

For illustrative purposes, the integrated circuit packaging system 100 is shown with the test pads 218 below the integrated circuit 102 and not below the interconnect contacts 110, although it is understood that the integrated circuit packaging system 100 can have a different configuration for the test pads 218. For example, the test pads 218 can be below the device contacts 216 to provide the shortest signal path between the integrated circuit 102 and the test pads 218. This configuration minimizes signal discontinuities that can affect signal integrity. As another example, the test pads 218 can be below the interconnect contacts 110. As a further example, the test pads 218 can be at the first side 108 of the interposer 104.

Also for illustrative purposes, the integrated circuit packaging system 100 is shown with the integrated circuit 102 at the interior portion 220 of the interposer 104, although it is understood that the integrated circuit packaging system 100 can have the integrated circuit 102 at a different location over the interposer 104. For example, the integrated circuit 102 can be over the peripheral portion 112 of the interposer 104 not having the interconnect contacts 110.

Further for illustrative purposes, the integrated circuit packaging system 100 is shown with the integrated circuit 102 mounted over the first side 108, although it is understood that the integrated circuit packaging system 100 can have different devices mounted over the first side 108. For example, the other integrated circuits or passive devices can be mounted to the first side 108 adjacent to the integrated circuit 102.

It has been discovered that the present invention provides thin integrated circuit packaging system by eliminating encapsulation over the first integrated circuit. Eliminating molding process and wire-bonding process reduces cost, shortens cycle time, and improves reliability. Eliminating molding and bonded wires can also provide an ultra thin package for numerous applications, such as an internal stacking component in a package-in-package (PIP) system module.

It has also been discovered that the present invention provides faster signal transfer between the flip chip and the test pads with the solder bumps. The test pads under the solder bumps can reduce transmission line discontinuities for improved signal integrity testing. The test pads also protect the interconnect contacts for test probe impacts.

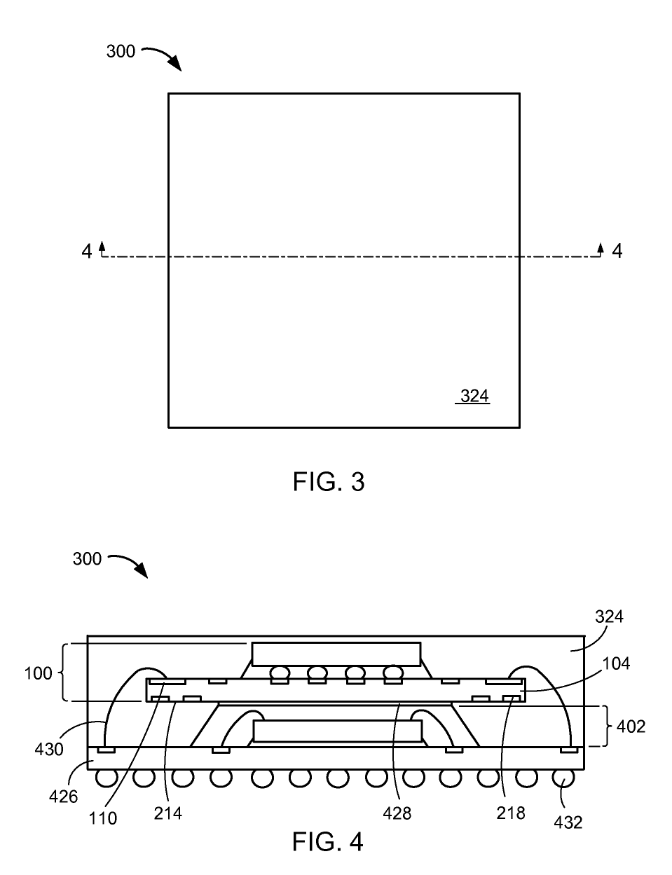

Referring now to FIG. 3, therein is shown a top view of an integrated circuit package-in-package system 300 in a first application example of the integrated circuit packaging system 100 of FIG. 1 in a second embodiment of the present invention. The integrated circuit package-in-package system 300 includes a package encapsulation 324, such as a cover including an epoxy molding compound.

For illustrative purposes, the integrated circuit package-in-package system 300 is shown with a square geometric shape, although it is understood that the shape of the integrated circuit package-in-package system 300 may be different. For example, the integrated circuit package-in-package system 300 can have a rectangular shape.

Referring now to FIG. 4, therein is shown a cross-sectional view of the integrated circuit package-in-package system 300 along line 4-4 of FIG. 3. The cross-sectional view depicts the integrated circuit package-in-package system 300 having an integrated circuit device 402, such as an encapsulated integrated circuit or encapsulated integrated circuits, over a carrier 426, such as a laminated substrate.

The integrated circuit packaging system 100 can be over the integrated circuit device 402 and the carrier 426. An adhesive 428, such as an adhesive film, can attach the second side 214 of the interposer 104 and the integrated circuit device 402. Internal interconnects 430, such as bond wires or ribbon bond wires, can connect the interconnect contacts 110 and the carrier 426.

The interconnect contacts 110 provide a sufficient large surface area for reliable and robust connection for connecting the internal interconnects 403. The test pads 218 can be used to test the integrated circuit packaging system 100, ensuring known good devices (KGD), without assembly into the integrated circuit package-in-package system 300. The package encapsulation 324 can be over the carrier 426 covering the integrated circuit packaging system 100, the integrated circuit device 402, and the internal interconnects 430.

External interconnects 432, such as solder balls, can connect to the carrier 426 on a side opposite the integrated circuit device 402. The external interconnects 432 connect to the next system level (not shown), such as printed circuit board or another integrated circuit packaging system.

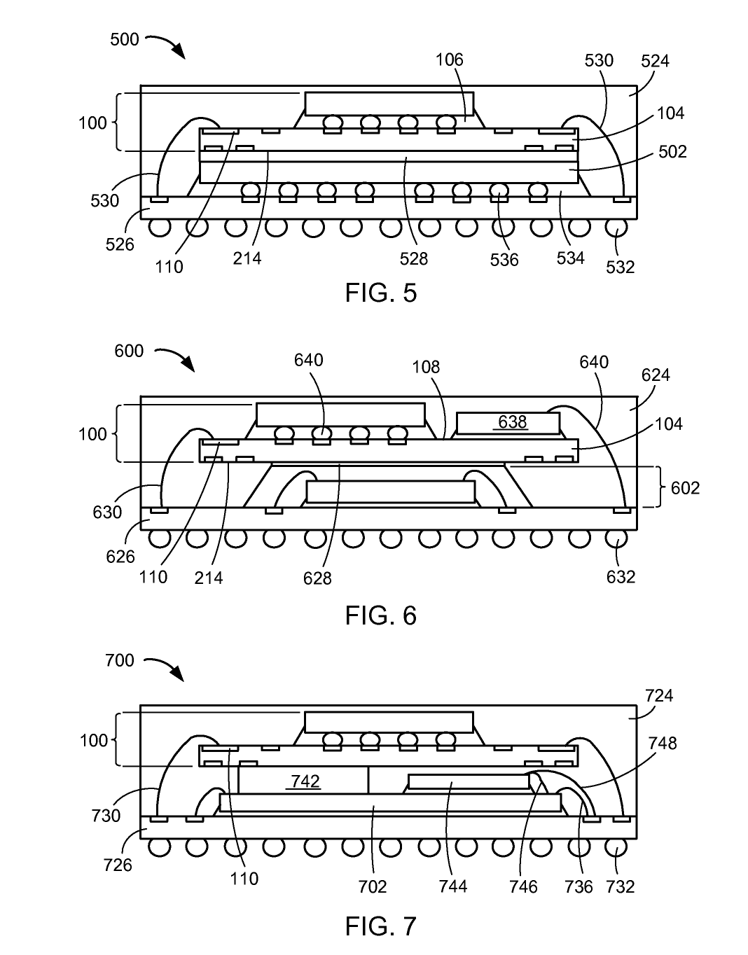

Referring now to FIG. 5, therein is shown a cross-sectional view of an integrated circuit package-in-package system 500 in a second application example of the integrated circuit packaging system 100 of FIG. 1 as exemplified by the top view of FIG. 3 in a third embodiment of the present invention. The cross-sectional view depicts the integrated circuit package-in-package system 500 having an integrated circuit device 502, such as a flip chip, over a carrier 526, such as a laminated substrate.

An underfill support 534 can be between the integrated circuit device 502 and the carrier 526. The underfill support 534 can be same material as the underfill 106 of the integrated circuit packaging system 100. The underfill support 534 can surround and provide structural support to device interconnects 536, such as solder bumps or conductive bumps, of the integrated circuit device 502. The device interconnects 536 can connect the integrated circuit device 502 and the carrier 526.

The integrated circuit packaging system 100 can be over the integrated circuit device 502 and the carrier 526. An adhesive 528, such as an adhesive film, can attach the second side 214 of the interposer 104 and the integrated circuit device 502. Internal interconnects 530, such as bond wires or ribbon bond wires, can connect the interconnect contacts 110 and the carrier 526. A package encapsulation 524, such as a cover including an epoxy molding compound, can be over the carrier 526 covering the integrated circuit packaging system 100, the integrated circuit device 502, and the internal interconnects 530.

External interconnects 532, such as solder balls, can connect to the carrier 526 on a side opposite the integrated circuit device 502. The external interconnects 532 connect to the next system level (not shown), such as printed circuit board or another integrated circuit packaging system.

Referring now to FIG. 6, therein is shown a cross-sectional view of an integrated circuit package-in-package system 600 in a third application example of the integrated circuit packaging system of FIG. 1 as exemplified by the top view of FIG. 3 in a fourth embodiment of the present invention. The cross-sectional view depicts the integrated circuit package-in-package system 600 having an integrated circuit device 602, such as an encapsulated integrated circuit or encapsulated integrated circuits, over a carrier 626, such as a laminated substrate.

The integrated circuit packaging system 100 can be over the integrated circuit device 602 and the carrier 626. An adhesive 628, such as an adhesive film, can attach the second side 214 of the interposer 104 and the integrated circuit device 602.

A second integrated circuit 638, such as an integrated circuit die, can be attached to the first side 108 of the interposer 104. Electrical interconnects 640, such as bond wires or ribbon bond wires, can connect the second integrated circuit 638 and the carrier 626.

Internal interconnects 630, such as bond wires or ribbon bond wires, can connect the interconnect contacts 110 and the carrier 626. A package encapsulation 624, such as a cover including epoxy molding compound, can be over the carrier 626 covering the integrated circuit packaging system 100, the integrated circuit device 602, the second integrated circuit 638, the electrical interconnects 640, and the internal interconnects 630.

External interconnects 632, such as solder balls, can connect to the carrier 626 on a side opposite the integrated circuit device 602. The external interconnects 632 connect to the next system level (not shown), such as printed circuit board or another integrated circuit packaging system.

Referring now to FIG. 7 is a cross-sectional view of an integrated circuit package-in-package system 700 in a fourth application example of the integrated circuit packaging system 100 of FIG. 1 as exemplified by the top view of FIG. 3 in a fifth embodiment of the present invention. The cross-sectional view depicts the integrated circuit package-in-package system 700 having an integrated circuit device 702, such as an integrated circuit die, over a carrier 726, such as a laminated substrate. Device interconnects 736, such as bond wires or ribbon bond wires, can connect the integrated circuit device 702 and the carrier 726.

A spacer 742, such as a wire-in-film spacer or an adhesive spacer, can be over the integrated circuit device 702. An intra-stack circuit 744, such as an integrated circuit die, can also be mounted over the integrated circuit device 702. The intra-stack circuit 744 can be adjacent to the spacer 742.

First intra-stack interconnects 746, such as bond wires or ribbon bond wires, can connect the intra-stack circuit 744 and the integrated circuit device 702. Second intra-stack interconnects 748, such as bond wires or ribbon bond wires, can connect the intra-stack circuit 744 and the carrier 726.

For illustrative purposes, the integrated circuit package-in-package system 700 is shown with the spacer 742 not covering the intra-stack circuit 744 and the first intra-stack interconnects 746, although it is understood that the integrated circuit package-in-package system 700 can have a different configuration for the spacer 742. For example, the spacer 742 can cover a portion of the first intra-stack interconnects 746 over the intra-stack circuit 744. As another example, the spacer 742 can be between over the intra-stack circuit 744 and not over the first intra-stack interconnects 746. As yet another example, a different spacer structure (not shown) can support the integrated circuit packaging system 100 over the intra-stack circuit 744.

The integrated circuit packaging system 100 can be over the intra-stack circuit 744 and the spacer 742. Internal interconnects 730, such as bond wires or ribbon bond wires, can connect the interconnect contacts 110 and the carrier 726. A package encapsulation 724, such as a cover including an epoxy molding compound, can be over the carrier 726 covering the integrated circuit packaging system 100, the integrated circuit device 702, the internal interconnects 730, the intra-stack circuit 744, the first intra-stack interconnects 746, the second intra-stack interconnects 746, and the spacer 742.

External interconnects 732, such as solder balls, can connect to the carrier 726 on a side opposite the integrated circuit device 702. The external interconnects 732 connect to the next system level (not shown), such as printed circuit board or another integrated circuit packaging system.

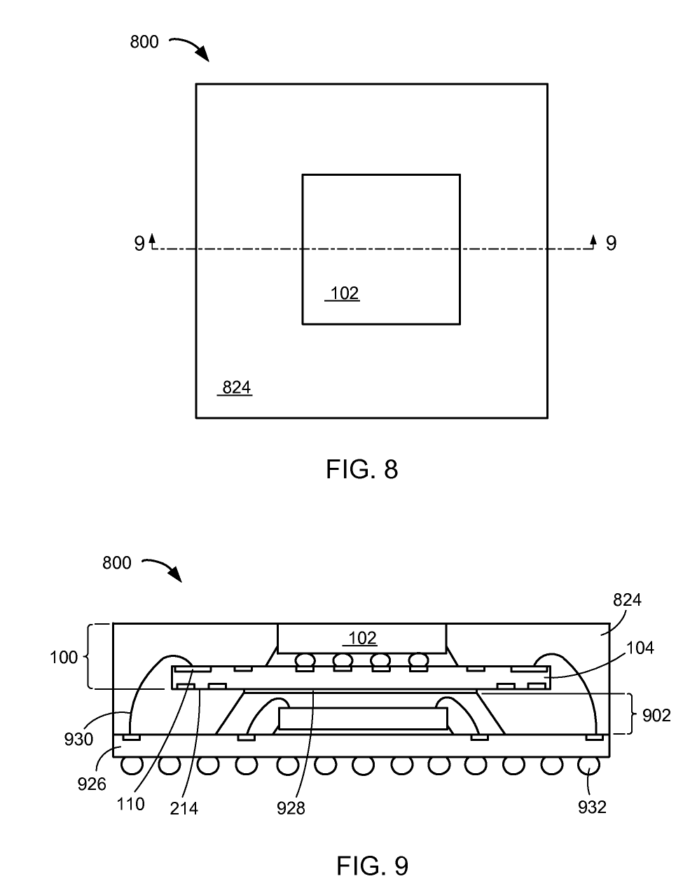

Referring now to FIG. 8, therein is shown a top view of an integrated circuit package-in-package system 800 in a fifth application example of the integrated circuit packaging system 100 of FIG. 1 in a sixth embodiment of the present invention. The top view depicts a package encapsulation 824, such as an epoxy molding compound, with the integrated circuit 102 exposed by the package encapsulation 824.

For illustrative purposes, the integrated circuit package-in-package system 800 is shown with a square geometric shape, although it is understood that the shape of the integrated circuit package-in-package system 800 may be different, such as rectangular or a geometric shape that is not a square.

Referring now to FIG. 9 is a cross-sectional view of the integrated circuit package-in-package system 800 along line 9-9 of FIG. 8. The cross-sectional view depicts the integrated circuit package-in-package system 800 having an integrated circuit device 902, such as an encapsulated integrated circuit or encapsulated integrated circuits, over a carrier 926, such as a laminated substrate.

The integrated circuit packaging system 100 can be over the integrated circuit device 902 and the carrier 926. An adhesive 928, such as an adhesive film, can attach the second side 214 of the interposer 104 and the integrated circuit device 902. Internal interconnects 930, such as bond wires or ribbon bond wires, can connect the interconnect contacts 110 and the carrier 926. The package encapsulation 824 can be over the carrier 926 covering the integrated circuit packaging system 100, the integrated circuit device 902, and the internal interconnects 930. The package encapsulation 824 can expose the integrated circuit 102 and can be coplanar with the exposed portion of the integrated circuit 102.

External interconnects 932, such as solder balls, can connect to the carrier 926 on a side opposite the integrated circuit device 902. The external interconnects 932 connect to the next system level (not shown), such as printed circuit board or another integrated circuit packaging system.

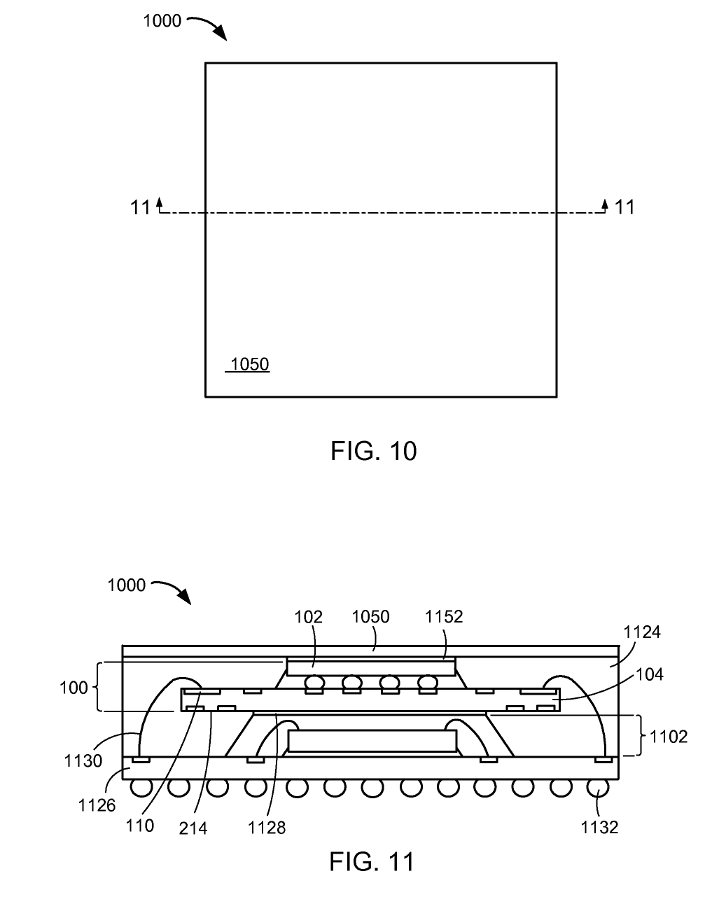

Referring now to FIG. 10, therein is shown a top view of an integrated circuit package-in-package system 1000 in a sixth application example of the integrated circuit packaging system 100 of FIG. 1 in a seventh embodiment of the present invention. The top view depicts a conductive structure 1050, such as a heat spreader.

For illustrative purposes, the integrated circuit package-in-package system 1000 is shown with a square geometric shape, although it is understood that the shape of the integrated circuit package-in-package system 1000 may be different. For example, the integrated circuit package-in-package system 1000 can have a rectangular shape.

Referring now to FIG. 11 is a cross-sectional view of the integrated circuit package-in-package system 1000 along line 11-11 of FIG. 10. The cross-sectional view depicts the integrated circuit package-in-package system 1000 having an integrated circuit device 1102, such as an encapsulated integrated circuit or encapsulated integrated circuits, over a carrier 1126, such as a laminated substrate.

The integrated circuit packaging system 100 can be over the integrated circuit device 1102 and the carrier 1126. An adhesive 1128, such as an adhesive film, can attach the second side 214 of the interposer 104 and the integrated circuit device 1102. Internal interconnects 1130, such as bond wires or ribbon bond wires, can connect the interconnect contacts 110 and the carrier 1126. A package encapsulation 1124 can be over the carrier 1126 covering the integrated circuit packaging system 100, the integrated circuit device 1102, and the internal interconnects 1130.

The conductive structure 1050 can be over the package encapsulation 1124. The conductive structure 1050 can attached to the integrated circuit 102 with an adhesive structure 1152, such as a thermal adhesive or a thermal film.

External interconnects 1132, such as solder balls, can connect to the carrier 1126 on a side opposite the integrated circuit device 1102. The external interconnects 1132 connect to the next system level (not shown), such as printed circuit board or another integrated circuit packaging system.

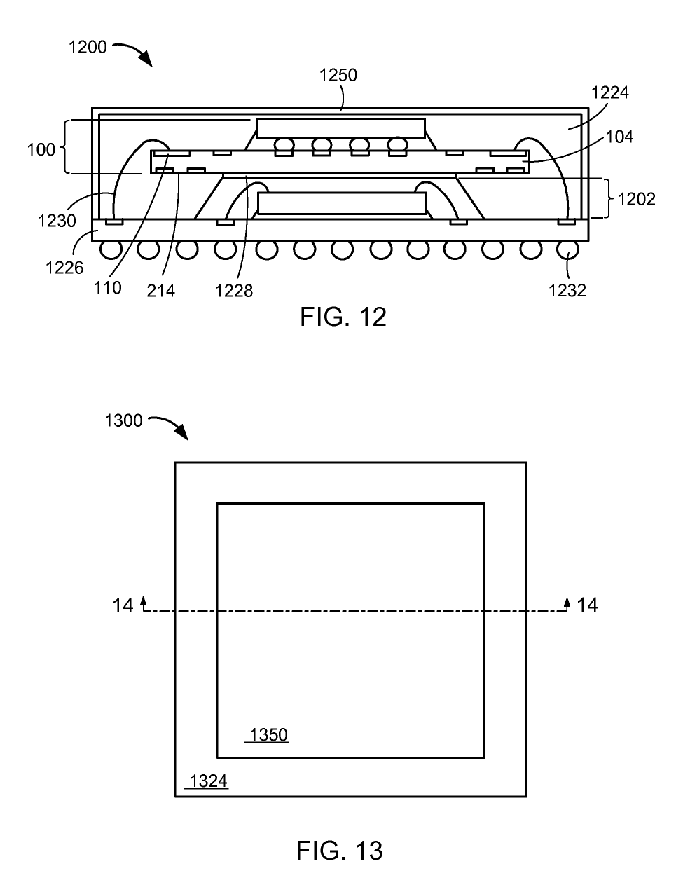

Referring now to FIG. 12 therein is shown a cross-sectional view of an integrated circuit package-in-package system 1200 in a seventh application example of the integrated circuit packaging system 100 of FIG. 1 as exemplified by the top view of FIG. 10 in an eighth embodiment of the present invention. The cross-sectional view depicts the integrated circuit package-in-package system 1200 having an integrated circuit device 1202, such as an encapsulated integrated circuit or encapsulated integrated circuits, over a carrier 1226, such as a laminated substrate.

The integrated circuit packaging system 100 can be over the integrated circuit device 1202 and the carrier 1226. An adhesive 1228, such as an adhesive film, can attach the second side 214 of the interposer 104 and the integrated circuit device 1202. Internal interconnects 1230, such as bond wires or ribbon bond wires, can connect the interconnect contacts 110 and the carrier 1226. A package encapsulation 1224 can be over the carrier 1226 covering the integrated circuit packaging system 100, the integrated circuit device 1202, and the internal interconnects 1230.

A conductive structure 1250, such as a conformal shielding layer, can be over the package encapsulation 1224. The conductive structure 1250 can attach the carrier 1226 for grounding allowing the conductive structure 1250 to function as an electromagnetic interference (EMI) shield.

External interconnects 1232, such as solder balls, can connect to the carrier 1226 on a side opposite the integrated circuit device 1202. The external interconnects 1232 connect to the next system level (not shown), such as printed circuit board or another integrated circuit packaging system.

Referring now to FIG. 13, therein is shown a top view of an integrated circuit package-in-package system 1300 in an eighth application example of the integrated circuit packaging system 100 of FIG. 1 in a ninth embodiment of the present invention. The top view depicts a package encapsulation 1324, such as an epoxy molding compound. The package encapsulation 1324 can expose a conductive structure 1350, such as an electromagnetic interference (EMI) shield.

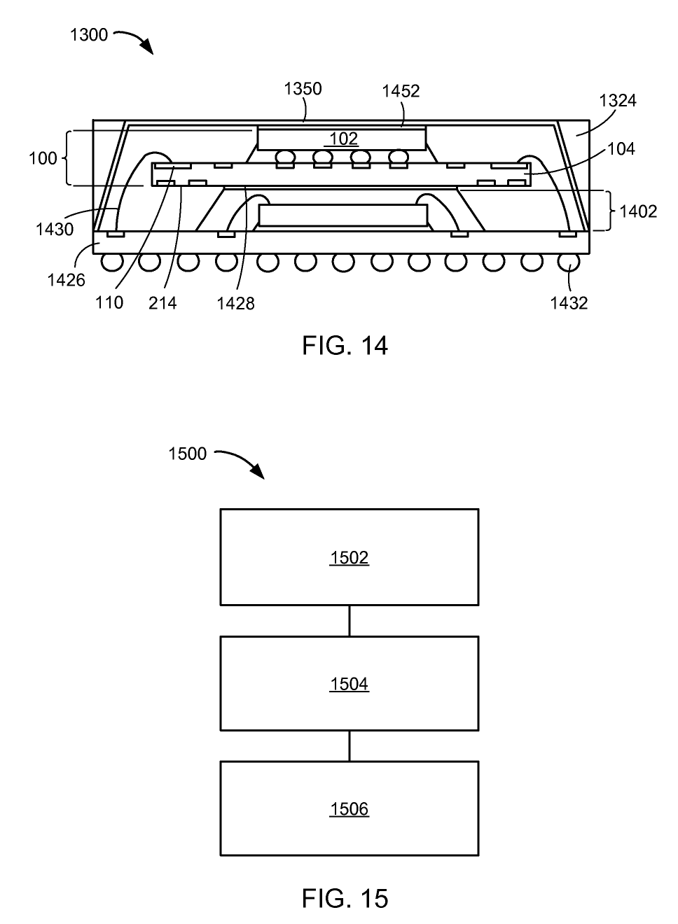

Referring now to FIG. 14 is a cross-sectional view of the integrated circuit package-in-package system 1300 along line 14-14 of FIG. 13. The cross-sectional view depicts the integrated circuit package-in-package system 1300 having an integrated circuit device 1402, such as an encapsulated integrated circuit or encapsulated integrated circuits, over a carrier 1426, such as a laminated substrate.

The integrated circuit packaging system 100 can be over the integrated circuit device 1402 and the carrier 1426. An adhesive 1428, such as an adhesive film, can attach the second side 214 of the interposer 104 and the integrated circuit device 1402. Internal interconnects 1430, such as bond wires or ribbon bond wires, can connect the interconnect contacts 110 and the carrier 1426. The conductive structure 1350, such as a shield cage, can be over the integrated circuit packaging system 100. The integrated circuit 102 can attached to the conductive structure 1350 with an adhesive structure 1452, such as a conductive adhesive or a conductive film. The conductive structure 1350 can attach the carrier 1426 for grounding allowing the conductive structure 1350 to function as an electromagnetic interference (EMI) shield.

The package encapsulation 1324 can be over the carrier 1426 covering the integrated circuit packaging system 100, the integrated circuit device 1402, the conductive structure 1350, and the internal interconnects 1430. The package encapsulation 1324 can expose the conductive structure 1350.

External interconnects 1432, such as solder balls, can connect to the carrier 1426 on a side opposite the integrated circuit device 1402. The external interconnects 1432 connect to the next system level (not shown), such as printed circuit board or another integrated circuit packaging system.

Referring now to FIG. 15, therein is shown a flow chart of a method 1500 of manufacture of an integrated circuit packaging system 100 in a further embodiment of the present invention. The method 1500 includes providing an interposer having a first side and a second side with the first side having a device contact and an interconnect contact and with the second side having a test pad in a block 1502; mounting an integrated circuit over the device contact in a block 1504; and applying an underfill between the integrated circuit and the interposer in a block 1506.

Another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit packaging system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing an interposer having a first side and a second side with the first side having a device contact and an interconnect contact and with the second side having a test pad;
mounting an integrated circuit over the device contact; and
applying an underfill between the integrated circuit and the interposer.

2. The method as claimed in claim 1 wherein providing the interposer having the first side and the second side with the first side having the device contact and the interconnect contact includes:
providing the device contact at an interior portion of the first side; and
providing the interconnect contact at a peripheral portion of the first side.

3. The method as claimed in claim 1 wherein providing the interposer having the first side and the second side with the second side having the test pad includes providing the test pad in an array configuration.

4. The method as claimed in claim 1 wherein applying the underfill between the integrated circuit and the interposer includes exposing the interconnect contact.

5. The method as claimed in claim 1 further comprising:
mounting an integrated circuit device over a carrier;
mounting the interposer over the integrated circuit device;
connecting the interconnect contact and the carrier; and
forming a package encapsulation over the integrated circuit, the interposer, and the integrated circuit device over the carrier with the package encapsulation the only cover over the integrated circuit.

6. A method of manufacture of an integrated circuit packaging system comprising:
providing an interposer having a first side and a second side including:
providing the first side having a device contact and an interconnect contact with the device contact at an interior portion of the first side and the interconnect contact at a peripheral portion of the first side, and
providing the second side having a test pad;
mounting an integrated circuit over the device contact; and
applying an underfill between the integrated circuit and the interposer without covering the interconnect contact.

7. The method as claimed in claim 6 wherein providing the interposer having the first side and the second side includes providing the test pad under the integrated circuit.

8. The method as claimed in claim 6 wherein providing the interposer having the first side and the second side includes providing the test pad under the device contact.

9. The method as claimed in claim 6 wherein providing the interposer having the first side and the second side includes providing the test pad under the interconnect contact.

10. The method as claimed in claim 6 further comprising:
mounting an integrated circuit device over a carrier;
mounting the interposer over the integrated circuit device;
connecting the interconnect contact and the carrier;
forming a package encapsulation over the carrier covering the integrated circuit, the interposer, and the integrated circuit device; and
forming a conductive structure over the package encapsulation.

11. An integrated circuit packaging system comprising:
an interposer having a first side and a second side with the first side having a device contact and an interconnect contact and with the second side having a test pad;
an integrated circuit over the device contact; and
an underfill between the integrated circuit and the interposer.

12. The system as claimed in claim 11 wherein the interposer includes:
the device contact at an interior portion of the first side; and
the interconnect contact at a peripheral portion of the first side.

13. The system as claimed in claim 11 wherein the interposer includes the test pad in an array configuration.

14. The system as claimed in claim 11 wherein the underfill is not over the interconnect contact.

15. The system as claimed in claim 11 further comprising:
a carrier;
an integrated circuit device over the carrier;
a package encapsulation over the integrated circuit, the interposer, and the integrated circuit device over the carrier with the package encapsulation the only cover over the integrated circuit; and
wherein:
the interposer is over the integrated circuit device; and
the interconnect contact is connected to the carrier.

16. The system as claimed in claim 11 wherein:
the device contact at an interior portion of the first side;
the interconnect contact at a peripheral portion of the first side; and
the underfill not over the interconnect contact.

17. The system as claimed in claim 16 wherein the interposer includes the test pad under the integrated circuit.

18. The system as claimed in claim 16 wherein the interposer includes the test pad under the device contact.

19. The system as claimed in claim 16 wherein the interposer includes the test pad under the interconnect contact.

20. The system as claimed in claim 16 further comprising:
a carrier;
an integrated circuit device over the carrier;
a package encapsulation over the integrated circuit, the interposer, and the integrated circuit device over the carrier;
a conductive structure over the package encapsulation; and
wherein:
the interposer is over the integrated circuit device; and
the interconnect contact is connected to the carrier.
